(19) United States
(12) Patent Application Publication
(10) Pub. No.: US 2009/0283889 A1
(43) Pub. Date: Nov. 19, 2009

(54) INTEGRATED CIRCUIT PACKAGE SYSTEM

(76) Inventors: Byoung Wook Jang, Yong-in (KR); Junwoo Myung, Ichon-si (KR); JoHyun Bae, Seoul (KR)

Correspondence Address: LAW OFFICES OF MIKIO ISHIMARU, 333 W. EL CAMINO REAL, SUITE 330, SUNNYVALE, CA, 94087, US

(21) Appl. No.: 12/122,639

(22) Filed: May 16, 2008

(51) Int. Cl. H01L 23/538; H01L 21/56

(52) U.S. Cl. 257/686; 438/109; 257/E23.169

(57) ABSTRACT

An integrated circuit package system includes: providing a heat spreader; attaching an upper substrate to the heat spreader, the upper substrate having an upper through-opening provided therein; attaching a top semiconductor die to the heat spreader through the upper through-opening, the top semiconductor die having a top die interconnect to the upper substrate; attaching a base substrate to the upper substrate, the base substrate having a base through-opening provided therein larger than the upper through-opening; and attaching an external interconnect connected to the base substrate.

### TECHNICAL FIELD

The present invention relates generally to integrated circuit packages and more particularly to integrated circuit package systems.

### BACKGROUND ART

Demand continues for the electronic industry to provide products that are lighter, faster, smaller, multi-functional, more reliable, and more cost-effective. In order to meet these expanding requirements of so many and varied consumers, more electrical circuits need to be more highly integrated to provide the functions demanded.

Smaller and denser integrated circuits are required in many portable electronic products, such as cell phones, portable computers, voice recorders, etc. as well as in many larger electronic systems, such as cars, planes, industrial control systems, etc.

Manufacturers are seeking ways to include more features as well as reduce the size of the integrated circuits. To meet these needs, three-dimensional type integrated circuit packaging techniques have been developed and used. Packaging technologies are increasingly using smaller footprints with more circuits in three-dimensional packages. In general, package stacks made by stacking packages and stacked chip packages made by stacking chips in a package have been used.

The conventional vertically stacked multi-chip packages require space for forming electrical connections, such as with bond wires, and typically the space is formed by spacers, such as a blank silicon die or an interposer between the packages. These spacers limit the amount of height reduction possible.

One disadvantage with providing a stacked package assembly is that the thickness of the package is increased. This means that it is difficult to dissipate heat from interior stacked chips.

Further, semiconductor packages suitable for high speed and performance generate a large quantity of heat during the operation, which results in degeneration of performance.

Thus, a need still remains for finding solutions for increasing the thermal performance of or removing heat from chips of package systems.

In view of the ever-increasing commercial competitive pressures, along with growing consumer expectations and the diminishing opportunities for meaningful product differentiation in the marketplace, it is critical that answers be found for these problems.

Solutions to these problems have been long sought but prior developments have not taught or suggested any solutions and, thus, solutions to these problems have long eluded those skilled in the art.

### DISCLOSURE OF THE INVENTION

The present invention provides an integrated circuit package system that includes: providing a heat spreader; attaching an upper substrate to the heat spreader, the upper substrate having an upper through-opening provided therein; attaching a top semiconductor die to the heat spreader through the upper through-opening, the top semiconductor die having a top die interconnect to the upper substrate; attaching a base substrate to the upper substrate, the base substrate having a base through-opening provided therein larger than the upper through-opening; and attaching an external interconnect connected to the base substrate.

Certain embodiments of the invention have other aspects in addition to or in place of those mentioned above. The aspects will become apparent to those skilled in the art from a reading of the following detailed description when taken with reference to the accompanying drawings.

### BRIEF DESCRIPTION OF THE DRAWINGS

FIG. 1 is a cross-sectional view of an integrated circuit package system in a first embodiment of the present invention;

FIG. 2 is a cross-sectional view of an integrated circuit package system in a second embodiment of the present invention;

FIG. 3 is a cross-sectional view of an integrated circuit package system in a third embodiment of the present invention;

FIG. 4 is a cross-sectional view of an integrated circuit package system in a fourth embodiment of the present invention; and

FIG. 5 is a flow chart of an integrated circuit package system for manufacturing the integrated circuit package system in an embodiment of the present invention.

### BEST MODE FOR CARRYING OUT THE INVENTION

The following embodiments are described in sufficient detail to enable those skilled in the art to make and use the invention. It is to be understood that other embodiments would be evident based on the present disclosure, and that system, process, or mechanical changes may be made without departing from the scope of the present invention.

In the following description, numerous specific details are given to provide a thorough understanding of the invention. However, it will be apparent that the invention may be practiced without these specific details. In order to avoid obscuring the present invention, some well-known circuits, system configurations, and process steps are not disclosed in detail.

Likewise, the drawings showing embodiments of the system are semi-diagrammatic and not to scale and, particularly, some of the dimensions are for the clarity of presentation and are shown greatly exaggerated in the drawing FIGs. Similarly, although the views in the drawings for ease of description generally show similar orientations, this depiction in the FIGs. is arbitrary for the most part. Generally, the invention can be operated in any orientation.

Generally, the device can be operated in any orientation. In addition, where multiple embodiments are disclosed and described having some features in common, for clarity and ease of illustration, description, and comprehension thereof, similar and like features one to another will ordinarily be described with like reference numerals.

For expository purposes, the term “horizontal” as used herein is defined as a plane parallel to the plane or surface of the package, regardless of its orientation. The term “vertical” refers to a direction perpendicular to the horizontal as just defined. Terms, such as “above”, “below”, “bottom”, “top”, “side” (as in “sidewall”), “higher”, “lower”, “upper”, “over”, and “under”, are defined with respect to the horizontal plane.

The term “on” means that there is direct contact among elements.

The term “processing” as used herein includes deposition of material or photoresist, patterning, exposure, development, etching, cleaning, and/or removal of the material or photoresist as required in forming a described structure.

The term “system” as used herein refers to and is defined as the method and as the apparatus of the present invention in accordance with the context in which the term is used.

The term “footprint” as used herein refers to the x-y dimension of the package in the horizontal plane.

The term “junction-to-board thermal resistance” as used herein refers to the thermal resistance between an integrated circuit package and the board on which the integrated circuit package is mounted.

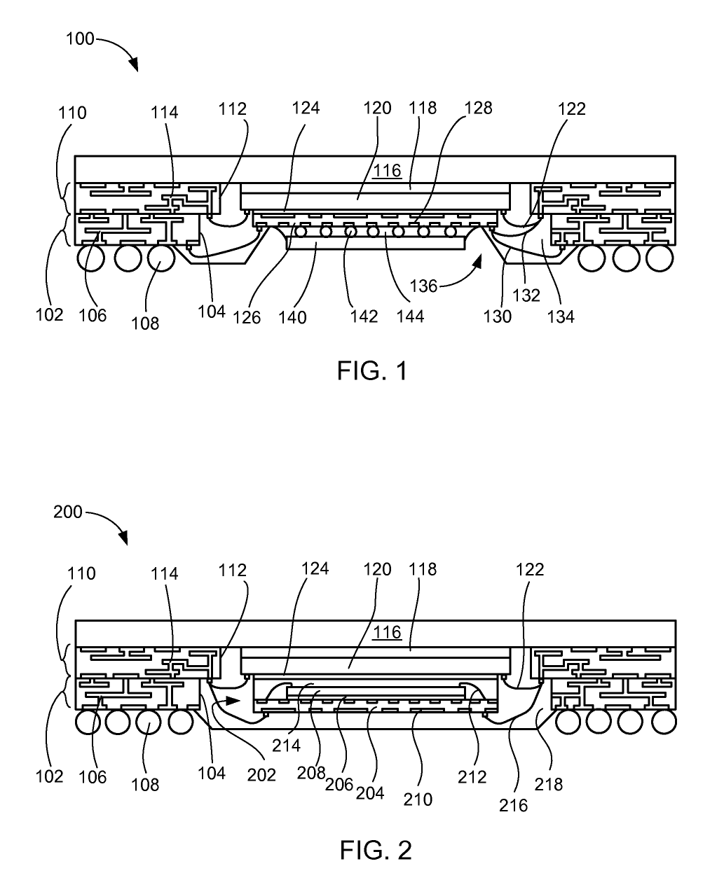

Referring now to FIG. 1, therein is shown a cross-sectional view of an integrated circuit package system 100 in a first embodiment of the present invention.

The integrated circuit package system 100 includes a base substrate 102 having a base through-opening 104 and a laminated structure, which includes base interconnections 106. The base interconnections 106 are wire traces and vias connected to pads on one or both surfaces of the base substrate 102. The base interconnections 106 are connected to external interconnects 108 for connection to an integrated circuit board or other package.

An upper substrate 110 has an upper through-opening 112, which is smaller than the base through-opening 104, and a laminated structure, which includes upper interconnections 114. The upper interconnections 114 are wire traces and vias connected to pads on one or both surfaces of the upper substrate 110.

The base substrate 102 and the upper substrate 110 are referred to as separate substrates as a matter of descriptive convenience since the substrates are both laminated structures and can be formed as a single laminated structure 102/110. In such a single laminated structure, the base through-opening 104 and the upper through-opening 112 would be a single stepped opening 104/112.

A heat spreader 116 is connected to the upper substrate 110 and may be in contact with some of the upper interconnections 114. The heat spreader 116 is formed from a suitable thermally conductive material, such as copper, aluminum, composites, or other materials. The outer perimeter of the heat spreader 116 is generally parallel to and the same size as the perimeter of the upper substrate 110.

A thermally conductive and adhesive die attach adhesive 118 is used to attach a top semiconductor die 120 to the heat spreader 116.

It has been discovered that making the combined thickness of the die attach adhesive 118 and the top semiconductor die 120 less than the thickness of the upper substrate 110 can minimize the thickness of the integrated circuit package system 100.

Top die interconnects 122, such as bond wires, connect the top semiconductor die 120 to the upper interconnections 114 of the upper substrate 110.

An adhesive 124 bonds an interposer 126 to the top semiconductor die 120 among the top die interconnects 122. The interposer 126 includes interposer interconnections 128, which are wire traces and vias connected to pads on one or both surfaces of the interposer 126.

The interposer interconnections 128 are connected by interposer interconnects 130, such as bond wires, to the base interconnections 106 of the base substrate 102 and by additional interposer interconnects 132, such as bond wires, to the upper interconnections 114 of the upper substrate 110. The interposer 126 is at least partially positioned within the base through-opening 104 of the base substrate 102.

An encapsulant 134 fills the through-openings 104 and 112 to protect the top die interconnects 122, the interposer interconnects 130, and the additional interposer interconnects 132. The encapsulant 134 also covers the perimeters of the interposer 126, the adhesive 124, the top semiconductor die 120, and the die attach adhesive 118 to bond against the heat spreader 116. The encapsulant 134 by virtue of encapsulating only the perimeter of the interposer 126 leaves an encapsulant opening 136 over the interposer 126.

An on-package or lower die 140 is attached through the encapsulant opening 136 by die external interconnects 142, such as solder balls, to the interposer 126. An underfill 144 protects the die external interconnects 142. The underfill 144 has a lower viscosity before curing than the encapsulant 134 and thus can fill the small space between the lower die 140 and the interposer 126 around the die external interconnects 142.

It has been discovered that the height of the integrated circuit package system 100 can be greatly reduced by having the interposer 126 and the lower die 140 with die external interconnects 142 within the base through-opening 104 of the base substrate 102. Further, the encapsulant 134 can be made to extend just above the height of the printed circuit board or other package when connected to the external interconnects 108.

The above arrangement provides a close connection between the top semiconductor die 120 and the heat spreader 116 and exposes the lower die 140 for rapid heat dissipation in a minimum height integrated circuit package system 100.

Since the lower die 140 can be a known-good-die, KGD or package, attached on to the interposer 126, the integrated circuit package system 100 may be referred to as a package-on-package (PoP) system.

Referring now to FIG. 2, therein is shown a cross-sectional view of an integrated circuit package system 200 in a second embodiment of the present invention.

The integrated circuit package system 200 includes the base substrate 102 having the base through-opening 104 and the base interconnections 106. The base interconnections 106 are connected to the external interconnects 108 for connection to an integrated circuit board or other package.

The upper substrate 110 has the upper through-opening 112 and the upper interconnections 114.

The heat spreader 116 is connected to the upper substrate 110 and may be in contact with some of the upper interconnections 114. The outer perimeter of the heat spreader 116 is generally parallel to and the same size as the perimeter of the upper substrate 110.

The thermally conductive and adhesive die attach adhesive 118 is used to attach the top semiconductor die 120 to the heat spreader 116.

It has been discovered that the thickness of the integrated circuit package system 100 can be minimized by making the combined thickness of the die attach adhesive 118 and the top semiconductor die 120 to be less than the thickness of the upper substrate 110.

The top die interconnects 122 connects the top semiconductor die 120 to the upper interconnections 114 of the upper substrate 110.

The adhesive 124 attaches a lower package 202 to the top semiconductor die 120.

The lower package 202 includes a lower package substrate 204 having a die attach adhesive 206 securing a lower die 208 thereto.

The lower package substrate 204 has lower package interconnections 210, which are connected by lower die interconnects 212, to the lower die 208. The lower die interconnects 212 are embedded in a lower package encapsulant 214. The lower package interconnections 210 further connect the lower die 208 to lower package interconnects 216, such as bond wires, which are connected to the upper substrate 110.

An encapsulant 218 fills the through-openings 104 and 112 and encapsulates the lower package interconnects 216 and the top die interconnects 122. The encapsulant 218 further encapsulates the bottom and sides of the lower package substrate 204, the lower package encapsulant 214, the adhesive 124, the top semiconductor die 120, and the die attach adhesive 118 on to the heat spreader 116.

Since the lower package 202, which can be a known-good-package or die, is encapsulated in the same encapsulant 218 as the top semiconductor die 120, the integrated circuit package system 200 may be referred to as a package-in-package (PiP) system.

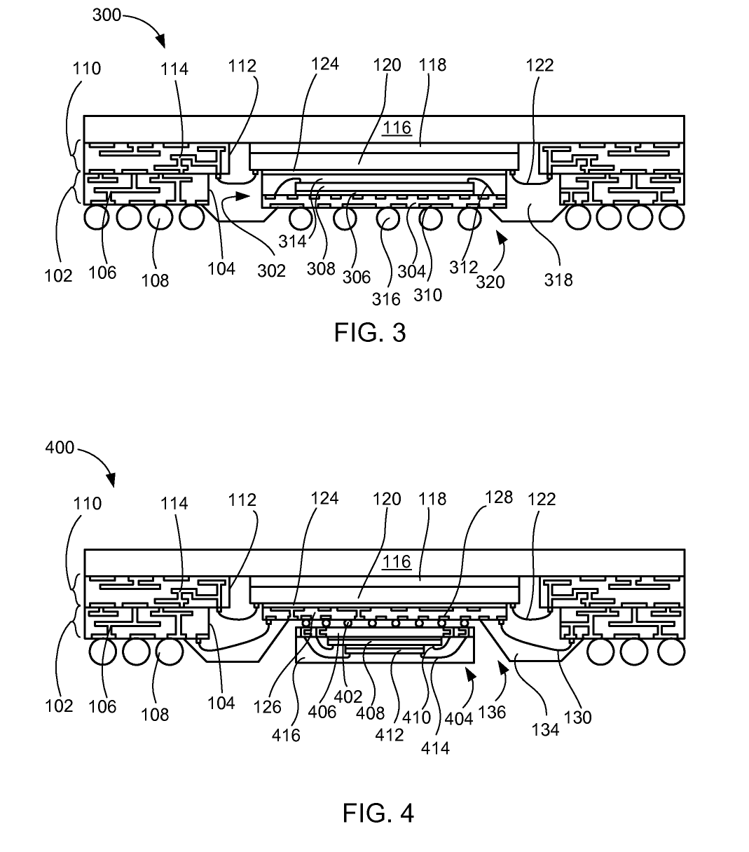

Referring now to FIG. 3, therein is shown a cross-sectional view of an integrated circuit package system 300 in the third embodiment of the present invention.

The integrated circuit package system 300 includes the base substrate 102 having the base through-opening 104 and the base interconnections 106. The base interconnections 106 are connected to the external interconnects 108 for connection to an integrated circuit board or other package.

The upper substrate 110 has the upper through-opening 112 and the upper interconnections 114.

The heat spreader 116 is connected to the upper substrate 110 and may be in contact with some of the upper interconnections 114. The outer perimeter of the heat spreader 116 is generally parallel to and the same size as the perimeter of the upper substrate 110.

The thermally conductive and adhesive die attach adhesive 118 is used to attach the top semiconductor die 120 to the heat spreader 116.

It has been discovered that the thickness of the integrated circuit package system 100 can be minimized by making the combined thickness of the die attach adhesive 118 and the top semiconductor die 120 to be less than the thickness of the upper substrate 110.

The top die interconnects 122 connects the top semiconductor die 120 to the upper interconnections 114 of the upper substrate 110.

The adhesive 124 attaches a lower package 302 to the top semiconductor die 120.

The lower package 302 includes a lower package substrate 304 having a die attach adhesive 306 securing a lower die 308 thereto.

The lower package substrate 304 has lower package interconnections 310, which are connected by lower die interconnects 312, to the lower die 308. The lower die interconnects 312 are embedded in a lower package encapsulant 314. The lower die interconnections 310 further connect the lower die 308 to external interconnects 316, such as solder balls.

An encapsulant 318 encapsulates the top die interconnects 122. The encapsulant 318 further encapsulates the sides of the lower package substrate 304, the lower package encapsulant 314, the die attach adhesive 124, the top semiconductor die 120 and the die attach adhesive 118 on to the heat spreader 116.

The encapsulant 318 leaves an encapsulant opening 320 with the lower package substrate 304 exposed for the external interconnects 316. The external interconnects 108 and 316 are in the same plane for connection simultaneously to a printed circuit board or other package.

Referring now to FIG. 4, therein is shown a cross-sectional view of an integrated circuit package system 400 in a fourth embodiment of the present invention.

The integrated circuit package system 400 includes the base substrate 102 having the base through-opening 104 and the base interconnections 106. The base interconnections 106 are connected to the external interconnects 108 for connection to an integrated circuit board or other package.

The upper substrate 110 has the upper through-opening 112 and the upper interconnections 114.

The heat spreader 116 is connected to the upper substrate 110 and may be in contact with some of the upper interconnections 114. The heat spreader 116 is formed from a suitable thermally conductive material, such as copper, aluminum, composites, or other thermally conductive materials. The outer perimeter of the heat spreader 116 is generally parallel to and the same size as the perimeter of the upper substrate 110.

The thermally conductive and adhesive die attach adhesive 118 is used to attach the top semiconductor die 120 to the heat spreader 116.

It has been discovered that the thickness of the integrated circuit package system 100 can be minimized by making the combined thickness of the die attach adhesive 118 and the top semiconductor die 120 to be less than the thickness of the upper substrate 110.

The top die interconnects 122 connects the top semiconductor die 120 to the upper interconnections 114 of the upper substrate 110.

The adhesive 124 bonds the interposer 126 to the top semiconductor die 120 among the top die interconnects 122. The interposer 126 includes the interposer interconnections 128, which are connected by the interposer interconnects 130 to the base interconnections 106 of the base substrate 102.

The encapsulant 134 fills the through-openings 104 and 112 to protect the interposer interconnect 130 and the top die interconnects 122. The encapsulant 134 also covers the perimeters of the interposer 126, the adhesive 124, the top semiconductor die 120, and the die adhesive 118 to bond on the heat spreader 116. The encapsulant 134 by virtue of encapsulating only the perimeter of the interposer 126 leaves the encapsulant opening 136 over the interposer 126.

An on-package or lower package 404 is attached through the encapsulant opening 136 by package external interconnects 402, such as solder balls, to the interposer 126. The lower package 404 has a lower package substrate 406 and contains a first integrated circuit die 408 die connected by first die interconnects 410 to the lower package substrate 406.

A second integrated circuit die 412 is die attached to the first integrated circuit die 408 and is connected by second die interconnects 414 to the lower package substrate 406.

An encapsulant 416 encapsulates the first and second die interconnects 410 and 414 and the second and first integrated circuit dies 412 and 408 on the lower package substrate 406.

This configuration is called a package-on-package system.

Thus, it has been discovered that the integrated circuit package system of the present invention furnishes important and heretofore unknown and unavailable solutions, capabilities, and functional aspects for stacked packages.

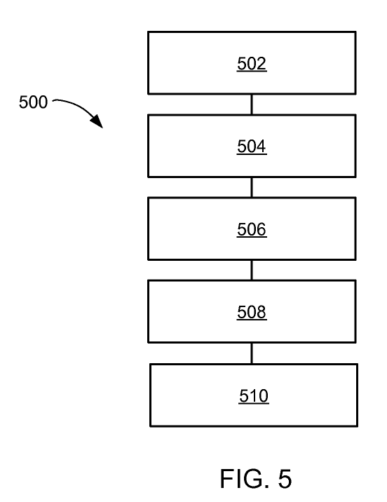

Referring now to FIG. 5, therein is shown a flow chart of an integrated circuit package system 500 for manufacturing the integrated circuit package system 100 in an embodiment of the present invention. The integrated circuit package system 500 includes: providing a heat spreader in a block 502; attaching an upper substrate to the heat spreader, the upper substrate having an upper through-opening provided therein in a block 504; attaching a top semiconductor die to the heat spreader through the upper through-opening, the top semiconductor die having a top die interconnect to the upper substrate in a block 506; attaching a base substrate to the upper substrate, the base substrate having a base through-opening provided therein larger than the upper through-opening in a block 508; and attaching an external interconnect connected to the base substrate in a block 510.

It has been discovered that the present invention is particularly advantageous in what is called a Fan-in Package-on-Package (Fi-PoP) system. The Fi-PoP package system allows stacking multiple logic, analog, and memory packages and for smaller conventional memory packages to be mounted with center ball grid array patterns.

The Fi-PoP package system is meant to deliver increased functional integration in a smaller footprint, flexibility in stacking conventional memory packages on top, improved final assembly yields, and a lower overall cost compared with conventional PoP solutions.

One disadvantage with providing a stacked package assembly is that the thickness of the package is increased. Additionally, there are reliability concerns due to the reduced possibilities for heat dissipation, which in turn lead to an increased risk of overheating.

Due to the large heat spreader possible with various embodiments of the present invention, the thermal emission performance can be greatly improved over other Fi-PoP package systems alleviating the problems associated with reliability and overheating.

While the invention has been described in conjunction with a specific best mode, it is to be understood that many alternatives, modifications, and variations will be apparent to those skilled in the art in light of the aforegoing description. Accordingly, it is intended to embrace all such alternatives, modifications, and variations that fall within the scope of the included claims. All matters hithertofore set forth herein or shown in the accompanying drawings are to be interpreted in an illustrative and non-limiting sense.

What is claimed is:

1. An integrated circuit package system comprising:
providing a heat spreader;
attaching an upper substrate to the heat spreader, the upper substrate having an upper through-opening provided therein;
attaching a top semiconductor die to the heat spreader through the upper through-opening, the top semiconductor die having a top die interconnect to the upper substrate;
attaching a base substrate to the upper substrate, the base substrate having a base through-opening provided therein larger than the upper through-opening; and
attaching an external interconnect connected to the base substrate.

2. The system as claimed in claim 1 further comprising:
attaching an interposer to the top semiconductor die through the base through-opening; and
attaching a lower die to the interposer.

3. The system as claimed in claim 1 further comprising:
attaching a lower package to the top semiconductor die through the base through-opening, the lower package including a lower package substrate and a lower die connected to the lower package substrate.

4. The system as claimed in claim 1 further comprising:
attaching a lower package to the top semiconductor die through the base through-opening, the lower package including a lower die connected to a lower package substrate and the lower package substrate having further external interconnects.

5. The system as claimed in claim 1 further comprising:
attaching an interposer to the top semiconductor die through the base through-opening; and
attaching a lower package to the interposer, the lower package including a lower package substrate attached to the interposer and a lower die connected to the lower package substrate.

6. An integrated circuit package system comprising:
providing a heat spreader;
attaching an upper substrate to the heat spreader, the upper substrate having an upper through-opening provided therein;
attaching a top semiconductor die to the heat spreader through the upper through-opening, the top semiconductor die having a top die interconnect to the upper substrate;
attaching a base substrate to the upper substrate, the base substrate having a base through-opening provided therein larger than the upper through-opening;
attaching an external interconnect connected to the base substrate; and
encapsulating the top semiconductor die and the top die interconnect on the heat spreader.

7. The system as claimed in claim 6 further comprising:
attaching an interposer to the top semiconductor die through the base through-opening, the interposer having an interposer interconnect connected to the upper substrate or the base substrate; and
attaching a lower die to the interposer, the lower die having a lower die interconnect to the interposer.

8. The system as claimed in claim 6 further comprising:
attaching a lower package to the top semiconductor die through the base through-opening, the lower package including a lower package substrate; a lower die connected to the lower package substrate; and an encapsulant encapsulating the lower die and attached to the top semiconductor die; and
connecting the lower package substrate to the upper substrate.

9. The system as claimed in claim 6 further comprising:
attaching a lower package to the top semiconductor die through the base through-opening, the lower package including a lower die connected to the lower package substrate, an encapsulant encapsulating the lower die, and the lower package substrate having further external interconnects.

10. The system as claimed in claim 6 further comprising:
attaching an interposer to the top semiconductor die through the base through-opening, the interposer having interposer interconnects to the base substrate; and
attaching a lower package to the interposer, the lower package including a lower package substrate attached to the interposer, a lower die connected to the lower package substrate, and an encapsulant encapsulating the lower die on the lower package substrate.

11. An integrated circuit package system comprising:
a heat spreader;
an upper substrate attached to the heat spreader, the upper substrate having an upper through-opening provided therein;
a top semiconductor die attached to the heat spreader through the upper through-opening, the top semiconductor die having a top die interconnect to the upper substrate;
a base substrate attached to the upper substrate, the base substrate having a base through-opening provided therein larger than the upper through-opening; and
an external interconnect connected to the base substrate.

12. The system as claimed in claim 11 further comprising:
an interposer attached to the top semiconductor die through the base through-opening; and
a lower die attached to the interposer.

13. The system as claimed in claim 11 further comprising:
a lower package attached to the top semiconductor die through the base through-opening, the lower package including a lower package substrate and a lower die connected to the lower package substrate.

14. The system as claimed in claim 11 further comprising:
a lower package attached to the top semiconductor die through the base through-opening, the lower package including a lower die connected to a lower package substrate and the lower package substrate having further external interconnects.

15. The system as claimed in claim 11 further comprising:
an interposer attached to the top semiconductor die through the base through-opening; and
a lower package attached to the interposer, the lower package including a lower package substrate attached to the interposer and a lower die connected to the lower package substrate.

16. The system as claimed in claim 11 further comprising:
an encapsulant encapsulating the top semiconductor die and the top die interconnect on the heat spreader.

17. The system as claimed in claim 16 wherein:
the interposer has an interposer interconnect connected to the upper substrate or the base substrate; and
the lower die has a lower die interconnect to the interposer.

18. The system as claimed in claim 16 further comprising:
a lower die connected to the lower package substrate;
an encapsulant encapsulates the lower die and is attached to the top semiconductor die; and
the lower package substrate is connected to the upper substrate.

19. The system as claimed in claim 16 further comprising:
an encapsulant encapsulating the lower die.

20. The system as claimed in claim 16 wherein:
the interposer has interposer interconnects connected to the base substrate; and
the lower package has an encapsulant encapsulating a lower die on a lower package substrate.
